(19) United States
(12) Patent Application Publication
(10) Pub. No.: US 2026/0150472 A1
(43) Pub. Date: May 28, 2026

(54) LIGHT EMITTING APPARATUS AND VEHICLE INCLUDING THE SAME

(71) Applicant: SEOUL VIOSYS CO., LTD., Ansan-si (KR)

(72) Inventors: Jina LEE, Ansan-si (KR); ChangYoun KIM, Ansan-si (KR)

(73) Assignee: SEOUL VIOSYS CO., LTD., Ansan-si (KR)

(21) Appl. No.: 19/395,933

(22) Filed: Nov. 20, 2025

Related U.S. Application Data
(60) Provisional application No. 63/724,926, filed on Nov. 26, 2024.
(60) Provisional application No. 63/748,560, filed on Jan. 23, 2025.

(51) Int. Cl. H10H 29/855; B60Q 1/26; H10H 20/841

(52) U.S. Cl. CPC H10H 29/855; H10H 20/841; B60Q 1/26; B60Q 2400/50

(57) ABSTRACT

A light emitting apparatus includes: a light transmissive layer that transmits light; and a light emitting module disposed on the light transmissive layer and having a light emitting surface that generates the light. The light emitting module includes: a plurality of light emitting devices that generate the light; and an optical layer for refracting the light generated from the plurality of light emitting devices. The optical layer is configured to refract the light generated from the plurality of light emitting devices such that a luminous intensity of the light traveling in a direction inclined at a predetermined angle with respect to a virtual line perpendicular to the light emitting surface is greater than a luminous intensity of the light traveling in a direction in which the virtual line extends.

### CROSS-REFERENCE TO RELATED APPLICATIONS

The present application claims the benefit of priority to U.S. Provisional Application No. 63/724,926, filed Nov. 26, 2024, and U.S. Provisional Application No. 63/748,560, filed Jan. 23, 2025, the entire contents of which are incorporated herein by reference.

### TECHNICAL FIELD

The present disclosure relates to a light emitting apparatus and a vehicle including the same.

### BACKGROUND

Recently, Light Emitting Diodes (LEDs) have been widely used. A light emitting diode converts an electrical signal into a form of light, such as infrared, visible, or ultraviolet light, using the properties of a compound semiconductor.

As the luminous efficiency of light emitting diodes is increased, light emitting devices are being applied to various fields including display apparatuses, lighting fixtures, and vehicles.

Recently, the need for a light emitting apparatus that irradiates light capable of displaying various information has been increasing.

### SUMMARY

Embodiments of the present disclosure may provide a light emitting apparatus capable of forming three-dimensional images such as figures, characters, and videos, and a vehicle including the same.

Embodiments of the present disclosure may provide a light emitting apparatus capable of increasing the visibility of three-dimensional images, and a vehicle including the same.

Embodiments of the present disclosure may provide a light emitting apparatus having a high luminous intensity at a specific viewing angle.

Embodiments of the present disclosure may provide a light emitting apparatus with improved reliability.

Embodiments of the present disclosure may provide a light emitting apparatus in which light transmittance is maintained under a specific condition in a plurality of light emitting devices.

Embodiments of the present disclosure may provide a light emitting apparatus that may reduce light loss and has improved light extraction efficiency.

Embodiments of the present disclosure may provide a light emitting apparatus with improved glare reduction.

In accordance with an aspect of the present disclosure, there is provided a light emitting apparatus, including: a light transmissive layer that transmits light; and a light emitting module disposed on the light transmissive layer and having a light emitting surface that generates the light, wherein the light emitting module includes: a plurality of light emitting devices that generate the light; and an optical layer for refracting the light generated from the plurality of light emitting devices, wherein the optical layer is configured for refracting the light generated from the plurality of light emitting devices such that a luminous intensity of the light traveling in a direction inclined at a predetermined angle with respect to a virtual line perpendicular to the light emitting surface is greater than a luminous intensity of the light traveling in a direction in which the virtual line extends.

Further, the light transmissive layer may be formed in plurality, and the plurality of light emitting devices may be located between the plurality of light transmissive layers.

Further, the light emitting module may further include a substrate, on a first surface of which the plurality of light emitting devices are disposed, and the optical layer may be in contact with another surface of the substrate opposite to the one surface.

Further, each of the plurality of light emitting devices may include: a first conductivity-type semiconductor layer; an active layer stacked on the first conductivity-type semiconductor layer; a second conductivity-type semiconductor layer stacked on the active layer; a transmissive layer stacked on the second conductivity-type semiconductor layer; and a reflective layer covering outer surfaces of the first conductivity-type semiconductor layer, the active layer, and the second conductivity-type semiconductor layer to reflect the light toward the transmissive layer.

Further, the light emitting module may further include: a substrate; an electrode that penetrates the reflective layer and is electrically connected to the first conductive-type semiconductor layer and the substrate, or to the second conductive-type semiconductor layer and the substrate; and a coating layer laminated on the substrate and configured to reflect light toward the light transmissive layer,

Further, the optical layer may include light diffusion particles that diffuse light.

Further, a plurality of optical protrusions for refracting light may be formed on one surface of the optical layer, and the plurality of optical protrusions may be arranged along the one surface of the optical layer.

Further, at least one of the optical protrusions may include: a first surface that protrudes from the one surface of the optical layer and is inclined at a predetermined first protrusion angle with respect to the one surface of the optical layer; and a second surface that protrudes from the one surface of the optical layer, may be inclined at a predetermined second protrusion angle, and may be connected to the first surface, and the first protrusion angle and the second protrusion angle may be different from each other.

Further, the first protrusion angle may be greater than the second protrusion angle so that the light generated from the plurality of light emitting devices may be reflected by the second surface and transmitted through the first surface.

Further, a length of the first surface in an extending direction of the first surface may be smaller than a length of the second surface in an extending direction of the second surface.

Further, the optical layer may be formed in plurality, and each of the plurality of optical layers may be stacked on a corresponding one of the plurality of light emitting devices.

Further, the light emitting apparatus may further include a bonding layer disposed between the optical layer and the light transmissive layer.

Further, the light emitting apparatus may further include a bonding layer disposed between the plurality of light emitting devices and the light transmissive layer.

Further, the light emitting module may further include a substrate on one surface of which the plurality of light emitting devices are disposed, the optical layer may be formed in plurality, the plurality of optical layers may include: a first optical layer covering the plurality of light emitting devices and stacked on the substrate; and a second optical layer located between the bonding layer and the light transmissive layer, and the bonding layer is disposed between the first optical layer and the second optical layer.

Further, the light emitting apparatus may further include: a first bonding layer disposed between the plurality of light emitting devices and the optical layer; and a second bonding layer disposed between the optical layer and the light transmissive layer.

Further, the light transmissive layer may be disposed between the plurality of light emitting devices and the optical layer.

In accordance with an aspect of the present disclosure, there is provided a light emitting apparatus, including: a light transmissive layer that transmits light; and a light emitting module disposed on the light transmissive layer and having a light emitting surface that generates light, wherein the light emitting module includes: a plurality of light emitting devices that generate the light; an optical layer that diffuses the light generated from the plurality of light emitting devices; and a refraction layer for refracting the light diffused by the optical layer, wherein the refraction layer is configured for refracting the light generated from the plurality of light emitting devices such that a luminous intensity of the light traveling in a direction inclined at a predetermined angle with respect to a virtual line perpendicular to the light emitting surface is greater than a luminous intensity of the light traveling in a direction in which the virtual line extends.

Further, a plurality of refraction protrusions for refracting the light may be formed on one surface of the refraction layer, the plurality of refraction protrusions may be arranged along the one surface of the refraction layer, and the optical layer may be disposed to face another surface of the refraction layer opposite to the one surface.

Further, the optical layer and the refraction layer may be disposed spaced apart from each other.

In accordance with an aspect of the present disclosure, there is provided a vehicle, including: a vehicle body; a light transmissive layer that is installed on the vehicle body inclined at a first predetermined angle with respect to a first virtual line extending in a front and rear direction of the vehicle body, and transmits light; and a light emitting module disposed on the light transmissive layer and having a light emitting surface that generates the light, wherein the light emitting module is disposed on the light transmissive layer such that a second angle, formed by a second virtual line perpendicular to the light emitting surface and the first virtual line, is greater than the first angle.

Embodiments of the present disclosure have an effect that, if light is not generated from a plurality of light emitting devices, light transmittance is maintained, and if light is generated from the plurality of light emitting devices, figures, characters, emoticons, pictures, or the like may be displayed.

Furthermore, embodiments of the present disclosure have an effect that, if light is not generated from the plurality of light emitting devices, light transmittance may be maintained, and thus a field of view may be ensured.

Furthermore, embodiments of the present disclosure have an effect of being able to increase the visibility of information displayed by a light emitting module.

Furthermore, embodiments of the present disclosure have an effect of being able to reduce light loss and improve the light extraction efficiency.

Furthermore, embodiments of the present disclosure have an effect of increasing reliability.

Furthermore, embodiments of the present disclosure have an effect of reducing glare.

Embodiments of the present disclosure may provide a light emitting apparatus having a high luminous intensity at a specific viewing angle.

Embodiments of the present disclosure may provide a light emitting apparatus with improved reliability.

### BRIEF DESCRIPTION OF THE DRAWINGS

FIG. 1 is a diagram illustrating a light emitting apparatus and a vehicle including the same according to a first embodiment of the present disclosure.

FIG. 2 is a diagram illustrating a light transmissive layer inclined at a predetermined angle with respect to a direction extending in a front and rear direction of the vehicle of FIG. 1.

FIG. 3 is a diagram illustrating the light emitting apparatus of the vehicle of FIG. 1.

FIG. 4 is a cross sectional view of the light emitting apparatus of FIG. 3, taken along line A-A′

FIG. 5 is a cross-sectional view of the light emitting apparatus of FIG. 3, taken along line B-B′.

FIG. 6 is a diagram illustrating a plurality of light emitting devices of the light emitting apparatus of FIG. 5.

FIG. 7 is a diagram illustrating an example of an optical layer of the light emitting module of FIG. 5.

FIG. 8 is a diagram illustrating an example of an optical layer of the light emitting module of FIG. 5.

FIG. 9 is a diagram illustrating an example of an optical layer of the light emitting module of FIG. 5.

FIG. 10 is a diagram illustrating an example of an optical layer of the light emitting module of FIG. 5.

FIG. 11 is a diagram illustrating an example of a light emitting apparatus according to a second embodiment of the present disclosure.

FIG. 12 is a diagram illustrating an example of the light emitting apparatus of FIG. 11.

FIG. 13 is a diagram illustrating an example of the light emitting apparatus of FIG. 11.

FIG. 14 is a diagram illustrating an example of the light emitting apparatus of FIG. 11.

FIG. 15 is a diagram illustrating an example of the light emitting apparatus of FIG. 11.

FIG. 16 is a diagram illustrating an example of the light emitting apparatus of FIG. 11.

FIG. 17 is a diagram illustrating an example of the light emitting apparatus of FIG. 11.

FIG. 18 is a diagram illustrating an example of the light emitting apparatus of FIG. 11.

FIG. 19 is a diagram illustrating an example of the light emitting apparatus of FIG. 11.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting apparatus 20 and a vehicle 1 including the same according to a first embodiment will be described.

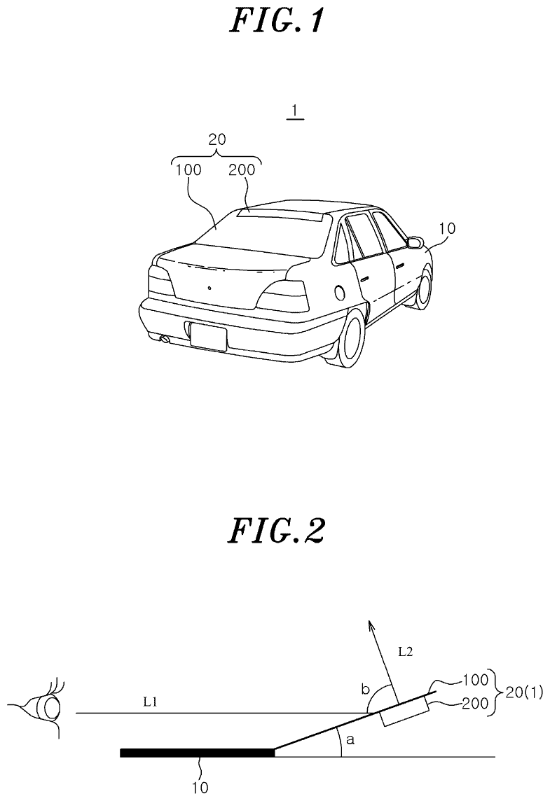

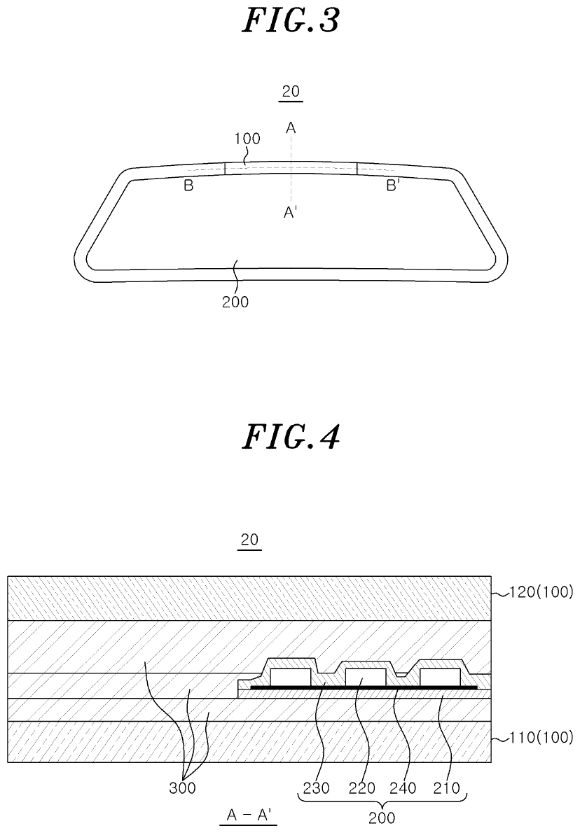

Referring to FIGS. 1 to 3, a vehicle 1 may transport people, cargo, or objects along a road. For example, the vehicle 1 may be configured as a truck, a passenger car, a bus, or the like. The vehicle 1 may include a vehicle body 10 and a light emitting apparatus 20.

The vehicle body 10 may provide the exterior of the vehicle 1. The vehicle body 10 may be configured to be movable on a road. A light emitting apparatus 20 may be installed on the vehicle body 10. The vehicle body 10 may include a power supply device for supplying power to the light emitting apparatus 20.

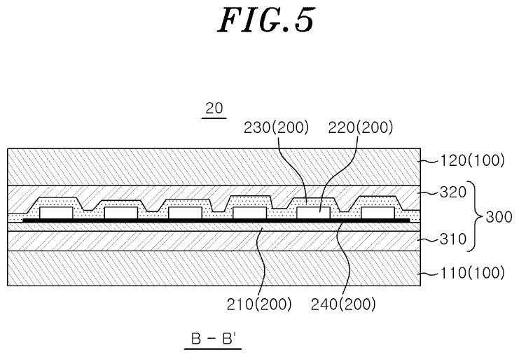

Referring further to FIGS. 4 and 5, the light emitting apparatus 20 may generate light. For example, the light emitting apparatus 20 may display characters, symbols, and videos. Furthermore, the light emitting apparatus 20 may be installed on the vehicle body 10. The light emitting apparatus 20 may be configured as a vehicle's window, windshield, rear window, taillight, headlight, rear lamp, tail lamp, interior light, brake light, grille lamp, or the like. Furthermore, the light emitting apparatus 20 may be installed and applied not only in vehicles, but also in various places composed of a plate having light transmittance, such as glass. In other words, the light emitting apparatus 20 may be applied to subway glass, bus glass, airplane windows, building exterior walls, building windows, outdoor advertisements, and the like. For example, the light emitting apparatus 20 may be installed on a subway window to display subway route map information. The light emitting apparatus 20 may include a light transmissive layer 100, a light emitting module 200, and a bonding layer 300.

Light may be transmitted through the light transmissive layer 100. The light transmissive layer 100 is formed of a material that transmits light and may include one or more of PMMA (Polymethyl Methacrylate), PC (Polycarbonate) resin, COP (Cyclo Olefin Polymer), acrylic resin, PE (Polyethylene), epoxy resin, and glass, quartz. For example, the light transmissive layer 100 may be a rear window of the vehicle 1.

Furthermore, the light transmissive layer 100 may be installed on the vehicle body 10 and inclined at a first predetermined angle “a” with respect to a first virtual line L1 extending in a front and rear direction of the vehicle body 10. The first angle “a” may be 20° to 50°. The first virtual line L1 may be the eye level of an observer viewing the light emitting apparatus 20, but is not limited thereto. A light emitting module 200 may be disposed on an inner side of the light transmissive layer 100. The light transmissive layer 100 may be formed to be larger than the light emitting module 200. In other words, the light transmissive layer 100 may be divided into a first region where the light emitting module 200 is disposed and a second region where the light emitting module 200 is not disposed and light is transmitted. The second region may be formed to be larger than the first region. Due to the second region, the transparency of the light emitting apparatus 20 may be increased.

Furthermore, a plurality of light transmissive layers 100 may be formed. The plurality of light transmissive layers 100 may include a first light transmissive layer 110 and a second light transmissive layer 120.

The first light transmissive layer 110 may be disposed closer to the interior of the vehicle body 10 than the second light transmissive layer 120. A light emitting module 200 and a bonding layer 300 may be stacked on the first light transmissive layer 110.

The second light transmissive layer 120 may be stacked on the light emitting module 200 and the bonding layer 300. In other words, the light emitting module 200 and the bonding layer 300 may be disposed between the first light transmissive layer 110 and the second light transmissive layer 120.

The light emitting module 200 may have a light emitting surface formed thereon that generates light. The light emitting module 200 may be disposed in the first region of the light transmissive layer 100. Furthermore, the light emitting module 200 may be disposed on the light transmissive layer 100 such that a second virtual line L2 extending in a direction perpendicular to the light emitting surface forms a second angle “b” with the first virtual line L1. The second angle “b” may be formed to be greater than the first angle “a”. For example, the second angle may be 40° to 70°. The light emitting module 200 may be configured such that the luminous intensity of light at the first virtual line L1 is greater than the luminous intensity of light at the second virtual line L2. For example, the luminous intensity of light at the first virtual line L1 may be 50% or more of the luminous intensity of light at the second virtual line L2. In other words, the light emitting module 200 may efficiently generate light toward an observer even when disposed inclined with respect to the front and rear direction of the vehicle 1.

The light emitting apparatus 20 of the vehicle 1 may satisfy the following minimum and maximum values according to a measurement position to satisfy visibility and stability. The luminous intensity measurement points at the first virtual line L1 may be 5D5L, 5DV, 5D5R.

| | | |
|---|---|---|
| Measurement Point | Minimum Value | Maximum Value |
| (degrees) | (cd) | (cd) |

| | | | |
|---|---|---|---|
| 10U | 10L | 8 | 110 |
| | V | 16 | 110 |
| | 10R | 8 | 110 |
| 5U | 10L | 16 | 110 |
| | 5L | 25 | 110 |
| | V | 25 | 110 |
| | 5R | 25 | 110 |
| | 10R | 16 | 110 |
| H | 10L | 16 | 110 |
| | 5L | 25 | 110 |
| | V | 25 | 110 |
| | 5R | 25 | 110 |
| | 10R | 16 | 110 |
| 5D | 10L | 16 | 110 |
| | 5L | 25 | 110 |
| | V | 25 | 110 |
| | 5R | 25 | 110 |
| | 10R | 16 | 110 |

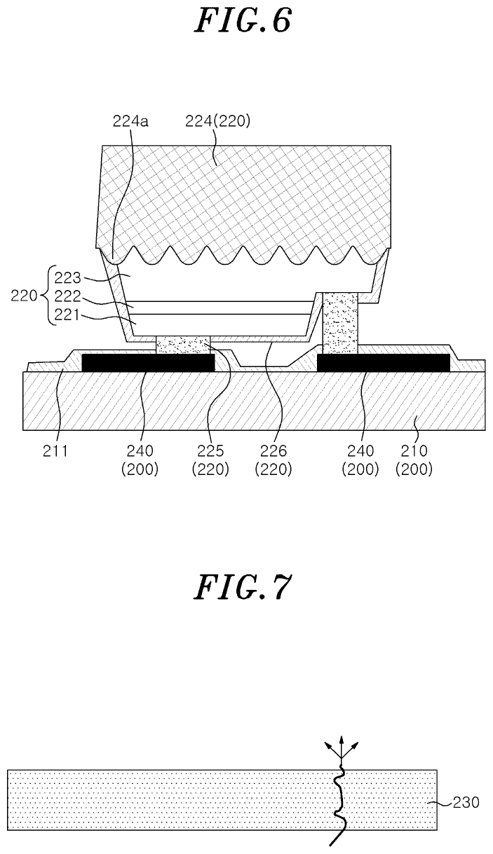

Referring further to FIG. 6, the light emitting module 200 may include a substrate 210, a plurality of light emitting devices 220, an optical layer 230, and a wiring 240.

The light emitting device 220, the wiring 240, and a coating layer 211 may be disposed on at least one surface of the substrate 210. For example, the substrate 210 may be a Printed Circuit Board (PCB). Furthermore, the substrate 210 may be made of a highly transparent material such as glass, sapphire, polyimide (PI), polycarbonate (PC), or polyethylene terephthalate (PET). However, this is merely an example, and the substrate 210 may include one or more of FR1, CEM-1, and FR-4. Here, FR1 is a material in which copper foil and laminate paper are stacked, and CEM-1 is a material in which copper foil, glass fiber fabric, laminate paper, and glass fiber fabric are sequentially stacked. Furthermore, FR-4 is a material in which copper foil and glass fiber fabric or glass fiber fabric are stacked. In addition, the substrate 210 may include a ceramic such as alumina (Al₂O₃), aluminum nitride (AlN), or ZTA (Zirconia Toughened Alumina).

Furthermore, the substrate 210 may include one or more of a high light-transmittance region and a low light-transmittance region. More light may be transmitted through the high light-transmittance region than the low light-transmittance region. The transparency of the light emitting apparatus 20 may be improved by this high light-transmittance region. The low light-transmittance region may adjust a light path such that less light is transmitted than in the high light-transmittance region. For example, the low light-transmittance region may refract or reflect light such that direct or indirect irradiation of the light onto a driver is minimized.

Furthermore, the coating layer 211 may be disposed on one surface of the substrate 210. The coating layer 211 may include at least one of fillers such as a reflective material for reflecting light and an absorbent material for absorbing light. The reflective material of the coating layer 211 may include TiO₂, BaSO₄, SiO₂, or the like. Light may be reflected toward the light transmissive layer 100 by the reflective material. The absorbent material of the coating layer 211 may include carbon black, chromium-based metal compounds (Cr₂O₃), nickel-chromium (Ni—Cr) alloys, graphene, or the like. Since light may be absorbed by the absorbent material of this coating layer 211, direct or indirect irradiation of light onto a driver may be minimized.

The light emitting device 220 may generate light. For example, the light emitting device 220 may be an element that converts electrical energy into light, such as a light emitting diode (LED), a laser diode, or an organic light emitting diode. In this case, the light emitting device 220 may generate UVC (200 nm˜280 nm), UVB (280 nm˜315 nm), UVA (315 nm˜420 nm), blue light, green light, yellow light, red light, infrared light, or the like. The light emitting device 220 is electrically connected to the wiring 240 and may receive power from an external source to generate light. A plurality of light emitting devices 220 may be formed and arranged along a surface of the substrate 210. The light emitting device 220 may include a first conductivity-type semiconductor layer 221, an active layer 222, a second conductivity-type semiconductor layer 223, a transmissive layer 224, an electrode 225, and a reflective layer 226.

The first conductivity-type semiconductor layer 221 may include p-type impurities (for example, Mg, Sr, Ba). In other words, the first conductivity-type semiconductor layer 221 may be a p-type semiconductor layer. However, this is merely an example, and the first conductivity-type semiconductor layer 221 may include n-type impurities. Furthermore, the first conductivity-type semiconductor layer 221 may be electrically connected to the substrate 210 through the wiring 240.

The active layer 222 may be disposed on the first conductivity-type semiconductor layer 221. In other words, the active layer 222 may be located between the first conductivity-type semiconductor layer 221 and the second conductivity-type semiconductor layer 223. Furthermore, the first conductivity-type semiconductor layer 221 and the active layer 222 may form a mesa.

The second conductivity-type semiconductor layer 223 may include n-type impurities (for example, Si, Ge, Sn). The second conductivity-type semiconductor layer 223 may be an n-type semiconductor layer. However, this is merely an example, and the second conductivity-type semiconductor layer 223 may include p-type impurities. Furthermore, the second conductivity-type semiconductor layer 223 may be electrically connected to the substrate 210 through the wiring 240.

The transmissive layer 224 may be stacked on the second conductivity-type semiconductor layer 223. The transmissive layer 224 may be an insulating or conductive substrate, and may also be an insulating or conductive substrate joined by bonding. Furthermore, the transmissive layer 224 may be an insulating or conductive substrate for growing the first conductivity-type semiconductor layer 221, the active layer 222, and the second conductivity-type semiconductor layer 223. For example, the transmissive layer 224 may include one or more of a silicon carbide substrate, a silicon substrate, a gallium nitride substrate, an aluminum nitride substrate, a sapphire substrate, or an Insulation Patterned Sapphire Substrate (IPSS). Furthermore, a transmissive layer unevenness 224a may be formed on the transmissive layer 224. Furthermore, the transmissive layer 224 may be omitted for a smaller thickness.

The transmissive layer unevenness 224a may be formed on a surface of the transmissive layer 224 opposite the second conductivity-type semiconductor layer 223. For example, the transmissive layer unevenness 224a may be formed in the shape of a triangular pyramid, a quadrangular pyramid, a polygonal pyramid, a semicircle, or the like. Furthermore, the transmissive layer unevenness 224a may include a material with a different composition from the transmissive layer 224. Due to this transmissive layer unevenness 224a, total internal reflection of light at the light transmissive layer 100 may be reduced, thus increasing the light extraction efficiency.

The electrode 225 may be electrically connected to the first conductivity-type semiconductor layer 221 and the wiring 240, or electrically connected to the second conductivity-type semiconductor layer 223 and the wiring 240. The electrode 225 may be formed of Cr, Pt, Au, W, or the like. Furthermore, the electrode 225 may include a reflective material for reflecting light toward the light emitting device 220. The reflective material of the electrode 225 may include Ag, Al, or the like.

The reflective layer 226 may be disposed to cover at least one of the first conductivity-type semiconductor layer 221, the active layer 222, and the second conductivity-type semiconductor layer 223 to reflect light. By this reflective layer 226, total internal reflection of light from the outer surface of at least one of the first conductivity-type semiconductor layer 221, the active layer 222, and the second conductivity-type semiconductor layer 223 may be reduced, thus increasing the light extraction efficiency.

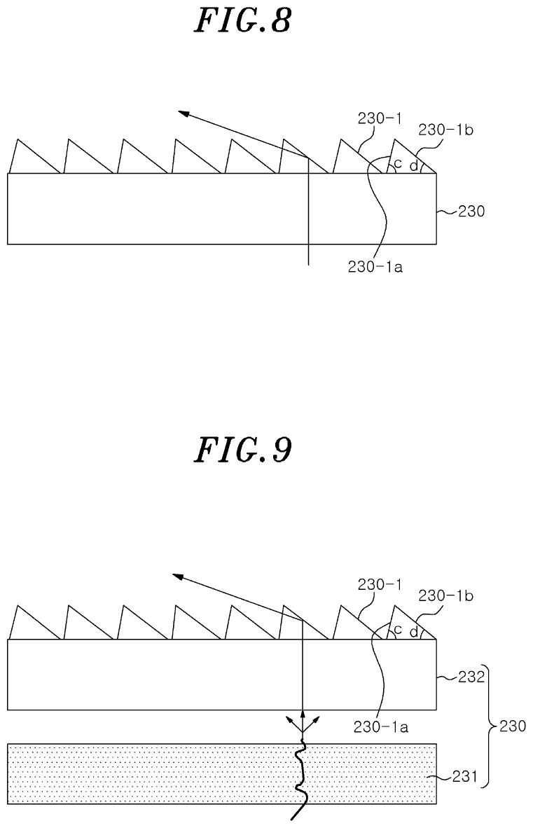

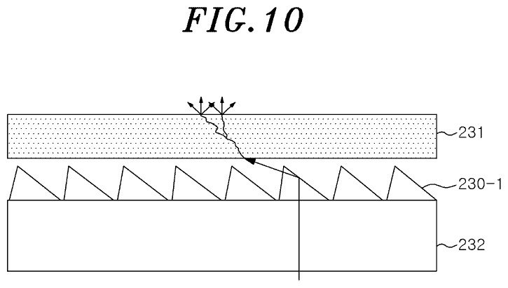

Referring further to FIGS. 7 to 10, the optical layer 230 may refract or diffuse the light generated from the plurality of light emitting devices 220. The optical layer 230 may be stacked on the substrate 210 so as to cover the plurality of light emitting devices 220 and the wiring 240. In other words, the optical layer 230 may cover the side surfaces and the upper surface of the plurality of light emitting devices 220 to adjust the path of light generated from the plurality of light emitting devices 220. The optical layer 230 may refract or diffuse light such that the intensity of light traveling in the direction of the first virtual line L1 is greater than the intensity of light traveling in the direction of the second virtual line L2 among the light generated from the plurality of light emitting devices 220. The optical layer 230 may be formed of a material having light transmittance, such as PMMA (acrylic), PC (polycarbonate), PS (polystyrene), PET, PDMS, UV curable resin, acrylic resin, urethane, silicone, PVC, or the like.

As an example, the optical layer 230 may include light-diffusion particles therein for diffusing light. In other words, the optical layer 230 may diffuse the light generated from the plurality of light emitting devices 220. The light-diffusion particles may include fine particles such as TiO₂, Silica, pore filler, Al₂O₃, or glass beads. Furthermore, it may be an optical layer in which a fine pattern for scattering light is formed on a light transmitting material such as PMMA (acrylic), PC (polycarbonate), or PS (polystyrene). The size of the fine pattern may be one-tenth or less of the size of the light emitting device.

As an example, a plurality of optical protrusions 230-1 may be formed on the optical layer 230. The plurality of optical protrusions 230-1 may be arranged along one surface of the optical layer 230. The one surface of the optical layer 230 may be the surface disposed on the opposite side of the surface facing the plurality of light emitting devices 220 among the two surfaces of the optical layer 230. For example, the optical protrusion 230-1 may be formed to have a cross-section of a triangular structure. In another embodiment, the optical protrusion 230-1 may be formed in a shape where the optical axis is biased in one direction, and may be, in addition to a triangular structure, a curved triangle, an asymmetric polygon, an incomplete parabola, an asymmetric curved surface, or a protrusion shape with a narrow radius of curvature in one direction. The optical layer 230 and the optical protrusion 230-1 may be formed of the same material, but are not limited thereto. If necessary, the optical protrusion 230-1 may be formed of a material having a different refractive index from the optical layer 230. Through this, the design difficulty may be reduced. Furthermore, the optical protrusion 230-1 may include a first surface 230-1a and a second surface 230-1b.

The first surface 230-1a may protrude from one surface of the optical layer 230 and be inclined at a predetermined first protrusion angle “c” with respect to the one surface of the optical layer 230. The first protrusion angle “c” may be equal to or greater than 50° and less than 90°.

The second surface 230-1b may protrude from one surface of the optical layer 230, be inclined at a predetermined second protrusion angle “d” with respect to the one surface of the optical layer 230, and be connected to the first surface 230-1a. The second protrusion angle “d” may be smaller than the first protrusion angle “c”. The second protrusion angle “d” may be equal to or greater than 20° and less than 45°. Due to this optical protrusion 230-1, light may be reflected and refracted and then transmitted through the first surface 230-1a.

As an example, the optical layer 230 may include a diffusion layer 231 and a refraction layer 232. The diffusion layer 231 may include light-diffusion particles. An optical protrusion 230-1 may be formed on the refraction layer 232. Furthermore, light that has passed through the diffusion layer 231 may be transmitted through the refraction layer 232. In other words, light may be diffused in the diffusion layer 231 and then reflected and refracted in the refraction layer 232.

As an example, the diffusion layer 231 may be disposed such that light that has passed through the refraction layer 232 is transmitted. In other words, light may be reflected and refracted in the refraction layer 232 and then diffused in the diffusion layer 231.

The wiring 240 may be disposed on one surface of the substrate 210 and electrically connected to the light emitting device 220. This wiring 240 may be a circuit line of the substrate 210. Furthermore, the wiring 240 may include a reflective material for reflecting the light generated from the light emitting device 220. The reflective material may include Ag, Al, Au, Ni, or the like. The reflectance of the reflective material of the wiring 240 may be 60% or more.

The bonding layer 300 may be disposed between the light emitting module 200 and the light transmissive layer 100 to bond the light emitting module 200 and the light transmissive layer 100. The bonding layer 300 may include, but is not limited thereto, PVB (Polyvinylbutyral), EVA (Ethylene Vinyl Acetate), SGP (SentryGlas Plus), TPU (Thermoplastic Polyurethane), silicone adhesive, synthetic polymers, or silicone resin, and may include any material having light transmitting properties. The bonding layer 300 may include a first bonding layer 310 and a second bonding layer 320.

The first bonding layer 310 may be disposed between the substrate 210 and the first light transmissive layer 110. The first bonding layer 310 is bonded to the substrate 210 and the first light transmissive layer 110 and may prevent the substrate 210 from shaking despite vibrations of the vehicle 1.

The second bonding layer 320 may be disposed between the optical layer 230 and the second light transmissive layer 120. The second bonding layer 320 is bonded to the optical layer 230 and the second light transmissive layer 120, may prevent the optical layer 230 from shaking due to vibrations of the vehicle 1, and may enhance moisture resistance to improve reliability.

Hereinafter, the operation and effects of the light emitting apparatus 20 and the vehicle 1 including the same according to the first embodiment will be described.

Light generated from the plurality of light emitting devices 220 of the light emitting apparatus 20 according to a first embodiment may be transmitted through the optical layer 230, the bonding layer 300, and the light transmissive layer 100. Furthermore, the light may be refracted or diffused when passing through the optical layer 230.

If light is not generated from the plurality of light emitting devices 220, light transmittance is maintained, and if light is generated from the plurality of light emitting devices 220, figures, characters, emoticons, pictures, or the like may be displayed.

Furthermore, since a total internal reflection of light in the light transmissive layer 100 may be prevented, a decrease in luminous intensity reaching an observer may be prevented.

Furthermore, since the intensity of light irradiated in the direction of the first virtual line L1 may be made greater than the intensity of light irradiated in the direction of the second virtual line L2 by the optical layer 230, visibility may be increased.

Furthermore, the light emitting module 200 may reduce light loss and improve the light extraction efficiency.

Furthermore, the light emitting module 200 has the effect of being able to reduce glare for a driver.

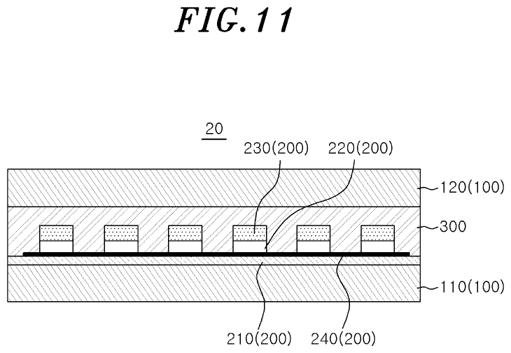

Hereinafter, a light emitting apparatus 20 and a vehicle 1 including the same according to a second embodiment will be described with reference to FIGS. 11 to 18. In describing the second embodiment, there is a difference in that the optical layer 230 may be disposed differently from the first embodiment, and this difference will be primarily described.

Referring to FIG. 11, as an example, a plurality of optical layers 230 may be formed. Furthermore, the plurality of optical layers 230 may be respectively stacked on the plurality of light emitting devices 220 and may be spaced apart from each other. Each of these plurality of optical layers 230 may refract or diffuse light generated from the upper surface of the light emitting device 220. Through this, design difficulty may be reduced. Furthermore, the bonding layer 300 may cover the side surfaces of the plurality of light emitting devices 220 and the outer surfaces of the plurality of optical layers 230. By this bonding layer 300, the light emitting device 220 and the optical layer 230 may be protected from the external environment, so reliability may be improved. The first light transmissive layer 110 may be disposed on one surface of the substrate 210. This first light transmissive layer 110 may protect the substrate 210. Furthermore, a reflective layer for reflecting light toward the optical layer 230 may be further disposed on the side surface of each of the plurality of light emitting devices 220. By the reflective layer, light extraction efficiency may be increased, improving the luminous intensity.

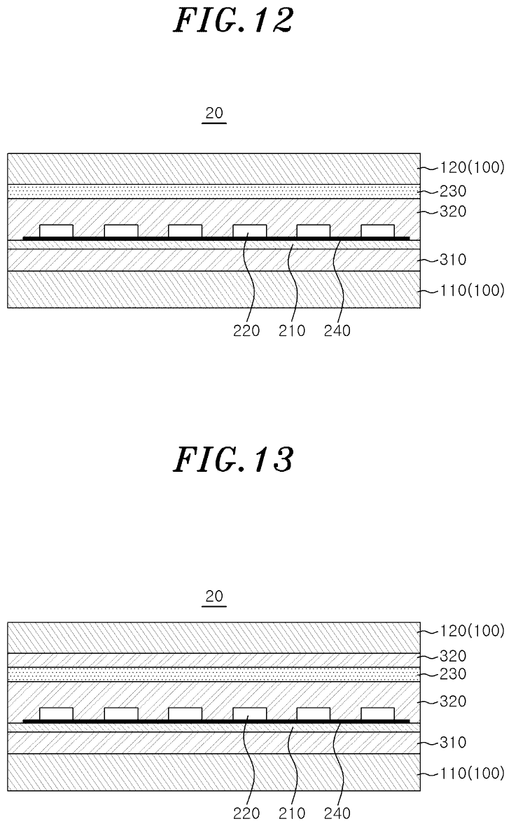

Referring to FIG. 12, as an example, the optical layer 230 may be disposed between the second bonding layer 320 and the light transmissive layer 100. In other words, the optical layer 230 may be disposed between the second bonding layer 320 and the second light transmissive layer 120 so as to be spaced apart from the plurality of light emitting devices 220. If the optical layer 230 is spaced apart from the plurality of light emitting devices 220, a sufficient path for light passing through the optical layer 230 is ensured, and the design difficulty may be reduced.

Referring to FIG. 13, as an example, the optical layer 230 may be disposed inside the second bonding layer 320. In other words, since both surfaces of the optical layer 230 may be bonded to the second bonding layer 320, the optical layer 230 may be stably fixed. Furthermore, since the plurality of light emitting devices 220 may be stably bonded to the second bonding layer 320, a change in the light path due to vibrations of the vehicle 1 may be prevented. The separation distance between the optical layer 230 and the light emitting device 220 may be formed to be smaller than the separation distance between the optical layer 230 and the second light transmissive layer 120, so that light loss may be minimized.

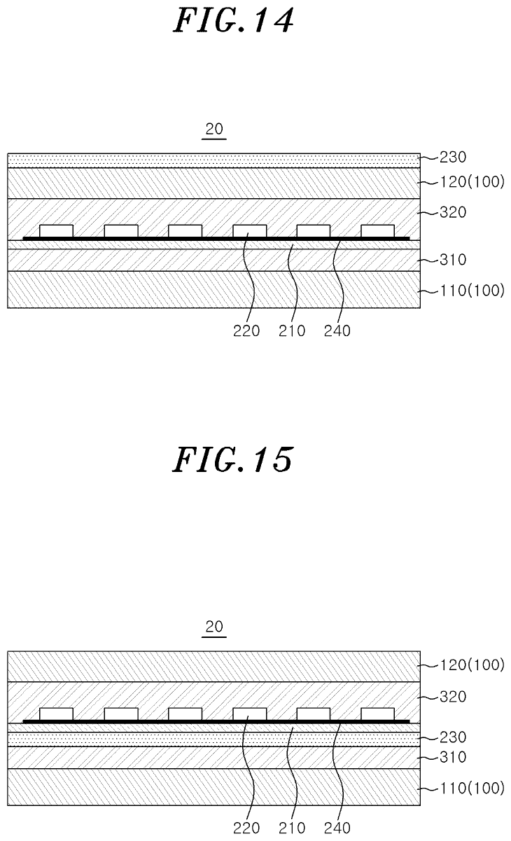

Referring to FIG. 14, as an example, the optical layer 230 may be stacked on the second light transmissive layer 120. In other words, the optical layer 230 may be exposed to the outside. The refractive index of the optical layer 230 exposed to the outside may be formed to be greater than the refractive index of the optical layer 230 disposed between the first light transmissive layer 110 and the second light transmissive layer 120.

Referring to FIG. 15, as an example, the optical layer 230 may be disposed between the substrate 210 and the first bonding layer 310. Furthermore, the optical layer 230 may further include one or more of a reflective material for reflecting light toward the second light transmissive layer 120 and an absorbent material for absorbing light. This optical layer 230 may reflect light to the outside of the vehicle body 10 or absorb light irradiated to the inside of the vehicle body 10.

Referring to FIG. 16, as an example, the optical layer 230 may be disposed on the outer surface of the first light transmissive layer 110. In other words, the first light transmissive layer 110 may be located between the optical layer 230 and the first bonding layer 310. Since the optical layer 230 may be disposed on the outer surface of the first light transmissive layer 110, the light refraction effect is increased, and the design difficulty may be reduced. Furthermore, the optical layer 230 may also be disposed on the outer surface of the second light transmissive layer 120. Through this, the light path exiting from the upper surface of the light emitting device 220 may be adjusted so that the luminous intensity of light at the first virtual line L1 becomes 50% or more of the luminous intensity of light at the second virtual line L2.

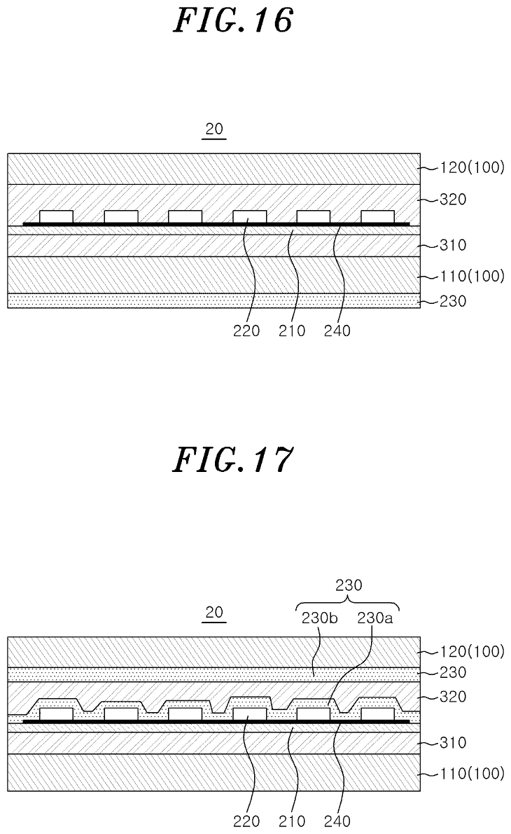

Referring to FIG. 17, as an example, a plurality of optical layers 230 may be formed. The plurality of optical layers 230 may include a first optical layer 230a and a second optical layer 230b. The first optical layer 230a may cover the plurality of light emitting devices 220 and the wiring 240. The second optical layer 230b may be disposed between the second bonding layer 320 and the second light transmissive layer 120. By the first optical layer 230a and the second optical layer 230b, a sufficient light path is ensured, and the light path may be efficiently adjusted.

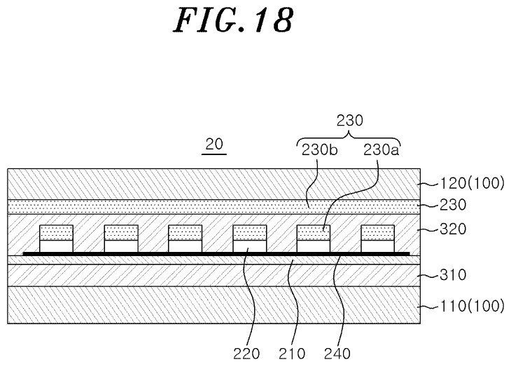

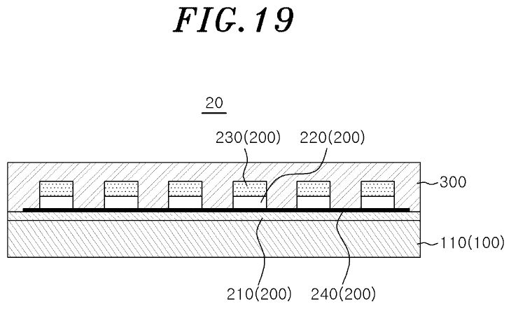

Referring to FIG. 18, as an example, a plurality of first optical layers 230a may be formed. Each of the plurality of first optical layers 230a may be stacked on each of the plurality of light emitting devices 220. The second optical layer 230b may be disposed between the second bonding layer 320 and the second light transmissive layer 120. By the first optical layer 230a and the second optical layer 230b, a sufficient light path is ensured, and the light path may be efficiently adjusted.

Referring to FIG. 19, as an example, a plurality of optical layers 230 may be formed. Furthermore, the plurality of optical layers 230 may be respectively stacked on the plurality of light emitting devices 220 and may be spaced apart from each other. Each of these plurality of optical layers 230 may refract or diffuse light generated from the upper surface of the light emitting device 220. Through this, the design difficulty may be reduced. Furthermore, the bonding layer 300 may cover the side surfaces of the plurality of light emitting devices 220 and the outer surfaces of the plurality of optical layers 230. By this bonding layer 300, the light emitting device 220 and the optical layer 230 may be protected from the external environment, so reliability may be improved. The first light transmissive layer 110 may be disposed on one surface of the substrate 210. This first light transmissive layer 110 may protect the substrate 210. The first light transmissive layer 110 may be disposed on an opposite side of the substrate on which the light emitting devices 220 are mounted. Furthermore, one surface of the bonding layer 300 may be exposed to the outside. This can reduce the optical interference.

Hereinafter, the operation and effects of the light emitting apparatus 20 and the vehicle 1 including the same according to the second embodiment will be described.

Light generated from the plurality of light emitting devices 220 of the light emitting apparatus 20 according to the second embodiment may be transmitted through one or more of the optical layers 230, the bonding layer 300, and the light transmissive layer 100. Furthermore, the light may be refracted or diffused when passing through the one or more optical layers 230.

By this light emitting apparatus 20, a sufficient light path is ensured, and the light path may be efficiently adjusted

Furthermore, by the light emitting apparatus 20, light may be reflected to the outside of the vehicle body 10 or light irradiated to the inside of the vehicle body 10 may be absorbed, so that direct or indirect irradiation of light onto a driver may be minimized.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

What is claimed is:

1. A light emitting apparatus, comprising:
a light transmissive layer having light transmittance; and
a light emitting module disposed on the light transmissive layer and having a light emitting surface,
wherein the light emitting module includes:
a plurality of light emitting devices configured to emit light; and
an optical layer configured to refract the light emitted from the plurality of light emitting devices,
wherein the optical layer is configured to refract the light emitted from the plurality of light emitting devices such that a luminous intensity of the light traveling in a direction inclined at a predetermined angle with respect to a virtual line perpendicular to the light emitting surface is greater than a luminous intensity of the light traveling in a direction in which the virtual line extends.

2. The light emitting apparatus of claim 1, wherein the light transmissive layer is formed in plurality, and
the plurality of light emitting devices are located between the plurality of light transmissive layers.

3. The light emitting apparatus of claim 1, wherein the light emitting module further comprises a substrate, on a first surface of which the plurality of light emitting devices are disposed, and
wherein the optical layer is in contact with a second surface of the substrate opposite to the first surface.

4. The light emitting apparatus of claim 1, wherein each of the plurality of light emitting devices comprises:
a first conductivity-type semiconductor layer;
an active layer stacked on the first conductivity-type semiconductor layer;
a second conductivity-type semiconductor layer stacked on the active layer;
a transmissive layer stacked on the second conductivity-type semiconductor layer; and
a reflective layer covering outer surfaces of the first conductivity-type semiconductor layer, the active layer, and the second conductivity-type semiconductor layer to reflect the light toward the transmissive layer.

5. The light emitting apparatus of claim 4, wherein the light emitting module further comprises:
a substrate;
an electrode that penetrates the reflective layer and is electrically connected to the first conductive-type semiconductor layer and the substrate, or to the second conductive-type semiconductor layer and the substrate; and
a coating layer laminated on the substrate and configured to reflect light toward the light transmissive layer.

6. The light emitting apparatus of claim 1, wherein the optical layer includes light diffusion particles that diffuse light.

7. The light emitting apparatus of claim 1, wherein a plurality of optical protrusions for refracting light are formed on one surface of the optical layer, and
the plurality of optical protrusions are arranged along the one surface of the optical layer.

8. The light emitting apparatus of claim 7, wherein at least one of the optical protrusions comprises:
a first surface that protrudes from the one surface of the optical layer and is inclined at a predetermined first protrusion angle with respect to the one surface of the optical layer; and
a second surface that protrudes from the one surface of the optical layer, is inclined at a predetermined second protrusion angle, and is connected to the first surface,
wherein the first protrusion angle and the second protrusion angle are different from each other.

9. The light emitting apparatus of claim 8, wherein the first protrusion angle is greater than the second protrusion angle so that the light generated from the plurality of light emitting devices is reflected by the second surface and transmitted through the first surface.

10. The light emitting apparatus of claim 9, wherein a length of the first surface in an extending direction of the first surface is smaller than a length of the second surface in an extending direction of the second surface.

11. The light emitting apparatus of claim 1, wherein the optical layer is formed in plurality, and
each of the plurality of optical layers is stacked on a corresponding one of the plurality of light emitting devices.

12. The light emitting apparatus of claim 1, further comprising a bonding layer disposed between the optical layer and the light transmissive layer.

13. The light emitting apparatus of claim 1, further comprising a bonding layer disposed between the plurality of light emitting devices and the light transmissive layer.

14. The light emitting apparatus of claim 13, wherein the light emitting module further comprises a substrate on one surface of which the plurality of light emitting devices are disposed,
the optical layer is formed in plurality,
the plurality of optical layers includes:
a first optical layer covering the plurality of light emitting devices and stacked on the substrate; and
a second optical layer located between the bonding layer and the light transmissive layer, and
the bonding layer is disposed between the first optical layer and the second optical layer.

15. The light emitting apparatus of claim 1, further comprising:
a first bonding layer disposed between the plurality of light emitting devices and the optical layer; and
a second bonding layer disposed between the optical layer and the light transmissive layer.

16. The light emitting apparatus of claim 1, wherein the light transmissive layer is disposed between the plurality of light emitting devices and the optical layer.

17. A light emitting apparatus, comprising:
a light transmissive layer that transmits light; and
a light emitting module disposed on the light transmissive layer and having a light emitting surface,
wherein the light emitting module comprises:
a plurality of light emitting devices configured to emit the light;
an optical layer that diffuses the light emitted from the plurality of light emitting devices; and
a refraction layer for refracting the light diffused by the optical layer,
wherein the refraction layer is configured for refracting the light emitted from the plurality of light emitting devices such that a luminous intensity of the light traveling in a direction inclined at a predetermined angle with respect to a virtual line perpendicular to the light emitting surface is greater than a luminous intensity of the light traveling in a direction in which the virtual line extends.

18. The light emitting apparatus of claim 17, wherein a plurality of refraction protrusions for refracting the light are formed on one surface of the refraction layer,
the plurality of refraction protrusions are arranged along the one surface of the refraction layer, and
the optical layer is disposed to face another surface of the refraction layer opposite to the one surface.

19. The light emitting apparatus of claim 18, wherein the optical layer and the refraction layer are disposed spaced apart from each other.

20. A vehicle, comprising:
a vehicle body;
a light transmissive layer that is installed on the vehicle body inclined at a first predetermined angle with respect to a first virtual line extending in a front and rear direction of the vehicle body, and transmits light; and
a light emitting module disposed on the light transmissive layer and having a light emitting surface that generates the light,
wherein the light emitting module is disposed on the light transmissive layer such that a second angle, formed by a second virtual line perpendicular to the light emitting surface and the first virtual line, is greater than the first angle.
